(19) United States
(12) Patent Application Publication
(10) Pub. No.: US 2007/0158053 A1
(43) Pub. Date: Jul. 12, 2007

(54) Cooling plant for one or more switch cabinets

(76) Inventors: Michael Nicolai, Rabenau (DE); Martin Dorrich, Sinn (DE)

Correspondence Address: PAULEY PETERSEN & ERICKSON, 2800 WEST HIGGINS ROAD, SUITE 365, HOFFMAN ESTATES, IL, 60195, US

(21) Appl. No.: 10/559,947

(22) PCT Filed: Jun. 7, 2004
(86) PCT No.: PCT/EP04/06114

§ 371 Date: Feb. 8, 2007

(30) Foreign Application Priority Data
Jun. 7, 2003 (DE) 103 25 929.5

(51) Int. Cl. H05K 7/20

(52) U.S. Cl. 165/122; 361/697; 165/104.33

(57) ABSTRACT

A cooling plant for cooling one or more switch cabinets. According to this invention, a large heat exchanger or several small heat exchangers operating in parallel are housed in a heat exchanger cabinet, wherein an inner space of the heat exchanger cabinet is coupled to a central air-conditioning device supplying cold air to a double bottom by an air inlet in the cabinet bottom and an air outlet of the double bottom. The cold air fed to the heat exchanger cabinet goes through the large heat exchanger or the small heat exchangers and cools the coolant flowing therein. The water supply and the water return of the large heat exchanger or the small heat exchangers are connected to the feed line and the return line of the switch cabinets that are to be cooled. This simple construction makes it possible to easily adapt the efficiency of cooling and the capacity to the variable number of switch cabinets.

### BACKGROUND OF THE INVENTION

1. Field of the Invention

This invention relates to a cooling installation for cooling one or several switchgear cabinets with heat-generating built-in devices arranged on top of each other inside the same, to which individual cooling bodies are assigned or which themselves are cooling bodies, wherein the cooling bodies are included in a coolant circuit fed from the water outlet side of an air/water heat exchanger via a feed line and a return line.

2. Discussion of Related Art

A cooling installation for cooling a switchgear cabinet is known from German Patent Reference DE 101 12 389 A1. In this cooling installation, the cooling bodies are embodied as plate-shaped receiver heat exchangers and are arranged in intermediate gaps between the built-in devices. The large air/water heat exchanger is arranged outside of the switchgear cabinet and must be connected with the output heat exchanger for the components of the cooling installation in the switchgear cabinet interior. The output heat exchanger is only cooled by the ambient air in the switchgear cabinet and thus has a limited heat exchange efficiency. Also, the construction of the switchgear cabinet with the cooling installation is complicated and expensive.

An arrangement for cooling a switchgear cabinet with heat-generating built-in devices arranged on top of each other in the interior is taught by German Patent Reference DE 696 17 089 T2. The built-in devices are cooled by a cooling air flow, generated by a central cooling air installation, and is fed to a hollow space between the double bottoms of the switchgear cabinet installation space. During this the cooling air flow is introduced via the bottom of the switchgear cabinet and flows upward through the remaining air conduits between the built-in devices and the switchgear cabinet housing and can exit into the switchgear cabinet installation space through air outlets in the top of the switchgear cabinet. Although it is possible to select the cooling air supplied to the switchgear cabinet interior to be colder than the room air, the effect of the cooling installation leaves something to be desired. This is particularly so because compact built-in devices with a considerably greater heat output are now housed in the switchgear cabinet interior at a greater component density.

### SUMMARY OF THE INVENTION

It is one object of this invention to provide a cooling installation of the type mentioned above but wherein the construction of the switchgear cabinet remains simple and one or several can be cooled by air/water heat exchangers which optimize a central air conditioning arrangement.

In accordance with this invention, this object is achieved with a large heat exchanger, or several, parallel operated small heat exchangers, each housed in a heat exchanger cabinet, wherein an interior of the heat exchanger cabinet is coupled via an air inlet opening in the cabinet bottom and an air outlet opening of a double bottom with a central air conditioning arrangement feeding cold air to the double bottom. The cold air supplied to the heat exchanger cabinet is conducted over the large heat exchanger or the small heat exchangers and cools the coolant flowing therein, and the water inflow and the water return flow of the large heat exchanger or the small heat exchangers are connected with the inflow line and the return flow line of the switchgear cabinets to be cooled.

The switchgear cabinets, which are compactly and completely occupied by built-in devices, can be simply connected with the heat exchanger and supplied with coolant for the cooling bodies. The heat exchanger cabinet has the large heat exchanger, or the parallel connected small heat exchangers, each receiving the cold air from a double bottom which is supplied with cold air by a central air conditioning arrangement. During this, the placement on and coupling of the heat exchanger cabinet with the double bottom remains simple. Also, it is possible to match the heat exchanger cabinet optimally to the switchgear cabinets to be cooled. The number of the cooling installation contains separate structural components, which can be placed without a large assembly cost outlay in an installation space and connected with each other.

In one design, a heat exchanger cabinet with a large heat exchanger of large exchange efficiency is embodied so that the large heat exchanger is installed inclined in the interior of the heat exchanger cabinet and extends over the entire height of the interior, while a heat exchanger cabinet with several small heat exchangers each is designed so that the small heat exchangers are arranged, horizontally aligned, on top of each other and fill the interior of the heat exchanger cabinet, except for small gaps between them.

In one case, for the flow of the coolant a pump and an expansion vessel are introduced into the inflow line of the large heat exchanger. In another case, a flow is achieved because individual pumps are introduced into the inflow lines of the small heat exchangers and an expansion vessel is additionally introduced into the inflow line of the uppermost small heat exchanger.

The circulation of the supplied cold air in the heat exchanger cabinet is improved because a fan is arranged on the heat exchanger cabinet, with an air aspiration opening connected with the interior of the heat exchanger cabinet via an air outlet opening of the latter. In this case, it is possible to provide for removal of the air heated in the meantime because the fan axially or radially removes the air aspirated from the interior of the heat exchanger cabinet into the air of the space surrounding the heat exchanger cabinet.

The parallel connection of the small air conditioners in the heat exchanger cabinet is simply provided in a space-saving manner because the small heat exchangers are connected in parallel by a vertical inflow line and a vertical return flow line which extend over the height of the interior of the heat exchanger cabinet. It is possible to improve the coolant circulation because the inflow line and the return flow line are connected with each other in the upper area of the interior via a connecting line with a venting device.

Placement of the inflow line and the return flow line in the heat exchanger cabinet is simplified if, in connection with a heat exchanger cabinet with a rack and sheathing elements, the inflow line and the return flow line are conducted in a receptacle or a hollow space of vertical frame legs of the rack.

In accordance with a further embodiment, the efficiency of cooling can be increased because the switchgear cabinets have built-in devices connected with a bottom opening in the double bottom and are supplied with cold air for additional cooling of the built-in devices.

### BRIEF DESCRIPTION OF THE DRAWINGS

This invention is explained in greater detail in view of exemplary embodiments, wherein:

FIG. 1 schematically shows a heat exchanger cabinet with a large heat exchanger; and

FIG. 2 schematically shows a heat exchanger cabinet with several small heat exchangers.

### DESCRIPTION OF PREFERRED EMBODIMENTS

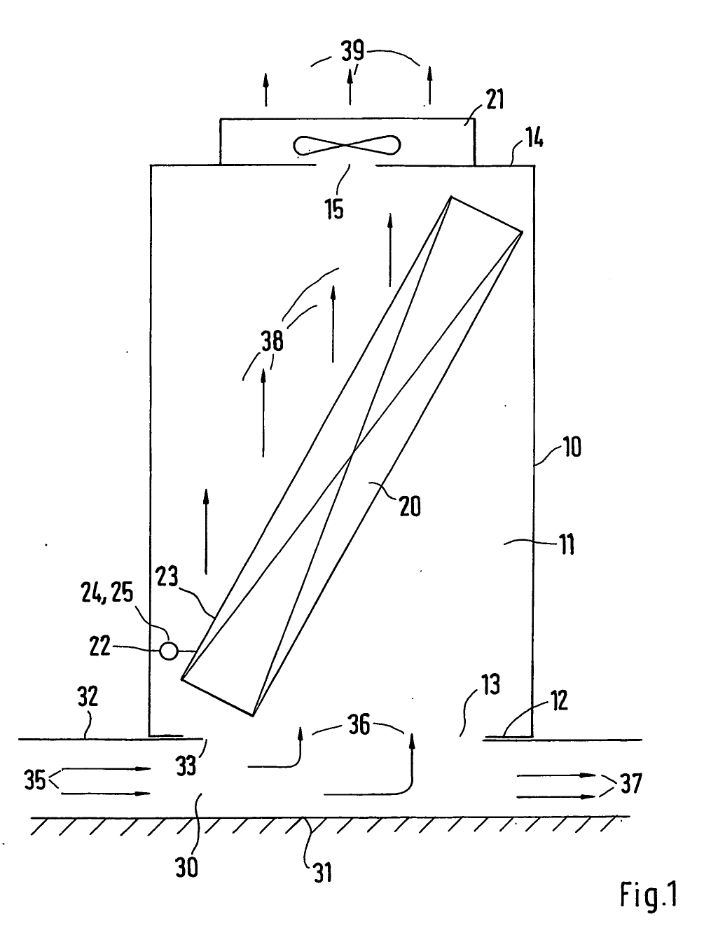

Different variations exist for the compact construction of a switchgear cabinet with servers as the built-in devices. The connection of the coolant circuit via an inflow line and a return flow line, which are conducted or routed out of the switchgear cabinet and connected with the corresponding connectors of an air/water heat exchanger, is common to them. For obtaining an adaptable construction of the cooling installation with one or several switchgear cabinets, this invention provides a heat exchanger cabinet 10, which receives a productive large heat exchanger 20 as shown in an exemplary embodiment in FIG. 1. On the water outlet side, this large heat exchanger 20 has an inflow connector 22 and a return flow connector 23, which can be extended out of the heat exchanger cabinet 10 and connected with the inflow line and return flow line of one or several switchgear cabinets. Inflow and return flow lines of the cooling bodies in the switchgear cabinets complete the coolant circuit, which is filled with coolant, for example water, in the installed position. The cooling bodies in the switchgear cabinets can be connected in parallel.

A pump 24 and an expansion vessel 25 are introduced into the inflow connector 22 of the large heat exchanger 20 in order to maintain flow and pressure in the coolant circuit. The cabinet bottom 12 has an air inlet opening 13 which, via an open air outlet opening 33 in the upper bottom element 32 of the double bottom 30, provides a connection between the interior 11 of the heat exchanger cabinet 10 with the central air conditioning arrangement, not shown, through the double bottom 30. The lower bottom element 32 closes off the double bottom 30. The central air conditioning arrangement feeds cold air 35 into the double bottom 30, a part 36 of which is supplied to the interior 11 of the heat exchanger cabinet 10. As indicated by the arrows 37, the remaining cold air 37 is conducted further in the double bottom 30. The part 36 flows through the large heat exchanger 20, which forms a multitude of air conduits and contacts the air 36 flowing through over a large contact surface and performs a heat exchange with the coolant flowing through the large heat exchanger 20. In the process the air flow is slightly heated and is aspirated through the air outlet opening 15 as heated air 38 by a fan 21 arranged on the roof 14 of the heat exchanger cabinet 10 and is removed again, for example axially, into the air surrounding the heat exchanger cabinet 10 as indicated by the arrows 39. Together with the cold air supply through the double bottom and the productivity of the central air conditioning arrangement, the large heat exchanger 20 can cool several switchgear cabinets which produce large amounts of heat. In this case the switchgear cabinets, supplied with coolant through the inflow connector 22 and the return flow connector 23, can also be connected with the double bottom 30 via an air inlet opening in the cabinet bottom and can receive cold air from there, for the interior, for additional cooling of the built-in devices.

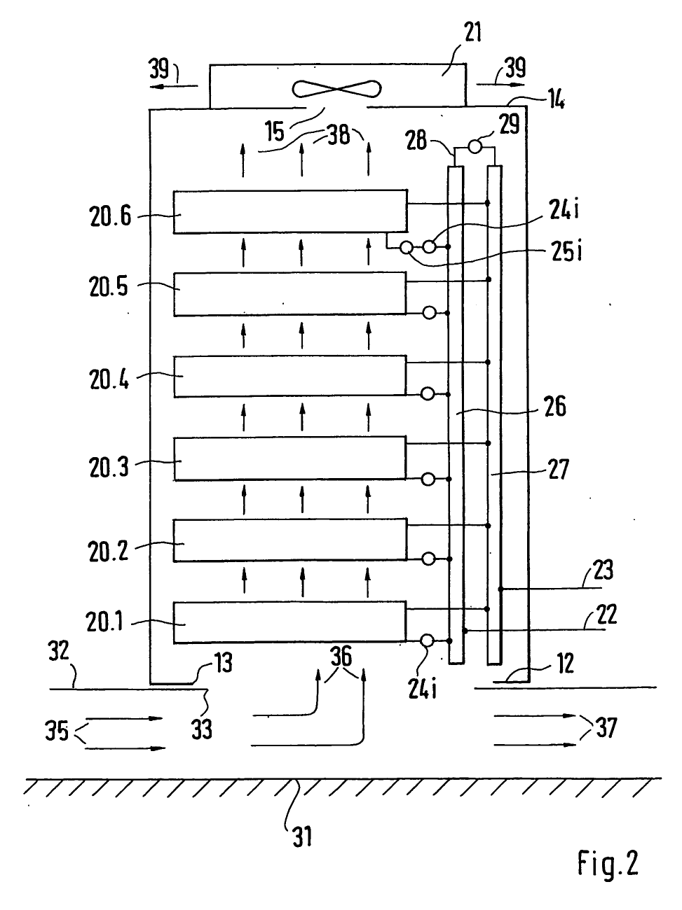

As shown by the exemplary embodiment in accordance with FIG. 2, with the identical connection with the double bottom 30, the heat exchanger cabinet 10 can receive several horizontally arrayed small heat exchangers 20.1, 20.2, 20.3, 20.4, 20.5 and 20.6, which are closely stacked, instead of one inclined installed large heat exchanger 20. An inflow line 26 and a return flow line 27 are conducted in a vertical conduit, which are led out of the heat exchanger cabinet 10 as the inflow connector 22 and the return flow connector 23 and are used for connections with the switchgear cabinets.

With their return flow lines, the small heat exchangers 20.1 to 20.6 are directly connected with the return flow line 27, while the inflow lines of the small heat exchangers 20.1 to 20.5 are connected via pumps 24i with the inflow line 26. In the uppermost small heat exchanger 20.6, an expansion vessel 25.1 is introduced into the inflow line, besides a pump 24i. The upper ends of the inflow line 26 and the return flow line 27 are connected with each other through a connecting line 28 with a venting device 29, so that the coolant circuit 20 can be vented.

As shown by the fan 21 placed on the roof 14 of the heat exchanger cabinet 10, it can also send the aspirated heated air 39 radially to the air surrounding the heat exchanger cabinet 10.

1. A cooling installation for cooling one or more switchgear cabinets with heat-generating built-in devices arranged on top of each other inside the switchgear cabinets, and to which individual cooling bodies are assigned or to which are embodied as cooling bodies, wherein the cooling bodies are included in a coolant circuit fed from a water outlet side of an air/water heat exchanger via a feed line and a return line, the cooling installation comprising:
one of a heat exchanger (20) and a plurality of parallel operated heat exchangers (20.1 to 20.6) housed in a heat exchanger cabinet (10) having an interior (11) coupled via an air inlet opening (13) in the cabinet bottom (12) and an air outlet opening (33) of a double bottom (30) with a central air conditioning arrangement feeding a cold air (36) to the double bottom (30),
the cold air (36) supplied to the heat exchanger cabinet (10) conducted over the one of the heat exchanger (20) and the parallel heat exchangers (20.1, 20.6) and cooling a coolant flowing therein, and
a water inflow (22) and a water return flow (23) of the one of the heat exchanger (20) and the parallel heat exchangers (20.1 to 20.6) connected with the feed line and the return line of each of the switchgear cabinets to be cooled.

2. The cooling installation in accordance with claim 1, wherein
the heat exchanger (20) is installed in an inclined position in the interior (11) of the heat exchanger cabinet (10) and extends over an entire height of the interior (11).

3. The cooling installation in accordance with claim 1, wherein
the parallel heat exchangers (20.1 to 20.6) are arranged horizontally aligned and on top of each other and nearly fill the interior (11) of the heat exchanger cabinet (10).

4. The cooling installation in accordance with claim 2, wherein
a pump (24) and an expansion vessel (25) are introduced into the water inflow (22) of the heat exchanger (20).

5. The cooling installation in accordance with claim 3, wherein
individual pumps (24i) are introduced into the water inflow (22) of the parallel heat exchangers (20.1 to 20.6), and
an expansion vessel (25i) is introduced into the inflow line of an uppermost one of the parallel heat exchangers (20.6).

6. The cooling installation in accordance with claim 5, wherein
a fan (21) is positioned on the heat exchanger cabinet (10) and has an air aspiration opening connected with the interior (11) of the heat exchanger cabinet (10) via an air outlet opening (15) of the heat exchanger cabinet (10).

7. The cooling installation in accordance with claim 6, wherein
the fan (21) one of axially and radially removes air (38) aspirated from the interior (11) of the heat exchanger cabinet (10) into air space surrounding the heat exchanger cabinet (10).

8. The cooling installation in accordance with claim 7, wherein
the parallel heat exchangers (20.1 to 20.6) are connected in parallel by a vertical inflow line (26) and a vertical return flow line (27) extending over a height of the interior (11) of the heat exchanger cabinet (10).

9. The cooling installation in accordance with claim 8, wherein
the inflow line (26) and the return flow line (27) are connected with each other in an upper area of the interior (11) via a connecting line (28) with a venting device (29).

10. The cooling installation in accordance with claim 10, wherein
in connection with the heat exchanger cabinet (10) with a rack and sheathing elements, the vertical inflow line (26) and the vertical return flow line (27) are routed in one of a receptacle and a hollow space of vertical frame legs of the rack.

11. The cooling installation in accordance with claim 10, wherein
each of the switchgear cabinets has a built-in device connected with a bottom opening in the double bottom (30) and is supplied with cold air for additional cooling of the built-in device.

12. The cooling installation in accordance with claim 1, wherein a pump (24) and an expansion vessel (25) are introduced into the water inflow (22) of the heat exchanger (20).

13. The cooling installation in accordance with claim 1, wherein individual pumps (24i) are introduced into the water inflow (22) of the parallel heat exchangers (20.1 to 20.6), and an expansion vessel (25i) is introduced into the inflow line of an uppermost one of the parallel heat exchangers (20.6).

14. The cooling installation in accordance with claim 1, wherein a fan (21) is positioned on the heat exchanger cabinet (10) and has an air aspiration opening connected with the interior (11) of the heat exchanger cabinet (10) via an air outlet opening (15) of the heat exchanger cabinet (10).

15. The cooling installation in accordance with claim 14, wherein the fan (21) one of axially and radially removes air (38) aspirated from the interior (11) of the heat exchanger cabinet (10) into air space surrounding the heat exchanger cabinet (10).

16. The cooling installation in accordance with claim 1, wherein the parallel heat exchangers (20.1 to 20.6) are connected in parallel by a vertical inflow line (26) and a vertical return flow line (27) extending over a height of the interior (11) of the heat exchanger cabinet (10).

17. The cooling installation in accordance with claim 16, wherein the vertical inflow line (26) and the vertical return flow line (27) are connected with each other in an upper area of the interior (11) via a connecting line (28) with a venting device (29).

18. The cooling installation in accordance with claim 17, wherein in connection with the heat exchanger cabinet (10) with a rack and sheathing elements, the inflow line (26) and the return flow line (27) are in one of a receptacle and a hollow space of vertical frame legs of the rack.

19. The cooling installation in accordance with claim 1, wherein each of the switchgear cabinets has a built-in device connected with a bottom opening in the double bottom (30) and is supplied with cold air for additional cooling of the built-in device.
